(19) United States
(12) Patent Application Publication
(10) Pub. No.: US 2009/0031955 A1
(43) Pub. Date: Feb. 5, 2009

(54) VACUUM CHUCKING HEATER OF AXISYMMETRICAL AND UNIFORM THERMAL PROFILE

(75) Inventors: Siqing Lu, San Jose, CA (US); Balaji Chandrasekaran, Santa Clara, CA (US); Paul Edward Gee, San Jose, CA (US); Nitin K. Ingle, Santa Clara, CA (US); Dmitry Lubomirsky, Cupertino, CA (US); Zheng Yuan, Fremont, CA (US); Ellie Y. Yieh, San Jose, CA (US)

Correspondence Address: MOSER IP LAW GROUP / APPLIED MATERIALS, INC., 1030 BROAD STREET, 2ND FLOOR, SHREWSBURY, NJ, 07702, US

(73) Assignee: APPLIED MATERIALS, INC., Santa Clara, CA (US)

(21) Appl. No.: 11/830,589

(22) Filed: Jul. 30, 2007

(51) Int. Cl. C23C 16/00; B23B 31/30

(52) U.S. Cl. 118/728; 279/3

(57) ABSTRACT

Embodiments of a vacuum chuck having an axisymmetrical and/or more uniform thermal profile are provided herein. In some embodiments, a vacuum chuck includes a body having a support surface for supporting a substrate thereupon; a plurality of axisymmetrically arranged grooves formed in the support surface, at least some of the grooves intersecting; and a plurality of chucking holes formed through the body and within the grooves, the chucking holes for fluidly coupling the grooves to a vacuum source during operation, wherein the chucking holes are disposed in non-intersecting portions of the grooves.

### BACKGROUND OF THE INVENTION

1. Field of the Invention

Embodiments of the present invention generally relate to vacuum chucks used in semiconductor fabrication, and more particularly, to vacuum chucking heaters having improved thermal profiles.

2. Description of the Related Art

Sub-atmospheric pressure chemical vapor deposition (SACVD) processes are carried out at reduced (or sub-atmospheric) pressure. The reduced pressure tends to decrease unwanted gas-phase reactions, thereby improving film uniformity across wafers. Many conventional SACVD processes provide high purity and uniformity of films and/or coatings, and conformal step coverage.

However, in certain applications, it has been observed that conventional SACVD processes may undesirably exhibit high thickness non-uniformity of deposited films, thereby reducing quality and yield. Such thickness non-uniformities are believed to be due, at least in part, to non-uniform thermal profiles of the substrate involved in the aforementioned processes. The non-uniform thermal profiles of the substrate may be due, at least in part, to non-uniform heat transfer between the vacuum chucking heater and the substrate.

The vacuum chucking heater generally includes a substrate support having a heater embedded therein with one or more grooves and vacuum chucking holes formed therein for retaining a workpiece (e.g., a semiconductor wafer) thereupon by maintaining a vacuum in the grooves when the workpiece is in place. Conventionally, other than by providing strong vacuum chucking power, the grooves and chucking holes formed in vacuum chucking heaters were not thought to contribute significantly to the quality of films deposited upon substrates disposed on conventional vacuum chucking heaters. However, the inventors have discovered that the size and locations of the grooves and chucking holes have a greater effect on resultant thermal profiles of substrates disposed thereon than previously appreciated. Moreover, the inventors have discovered that resultant thermal profiles from such conventional heaters are non-uniform enough to cause variations in film thickness for films deposited on such substrates. In some processes, for example, a one degree change in the thermal profile may correspond to an about 60-100 Angstrom per minute change in the thickness of a film deposited thereon. Therefore, such non-uniform thermal profiles may cause a large variation in the resultant thickness profile of films deposited on substrates utilizing such conventional vacuum chucking heaters, particularly as the overall thickness of the deposited films decrease.

For example, conventionally, one school of thought is that providing a strong chucking force between the substrate and the support enhances thermal contact therebetween and, therefore, improves the thermal profile of the substrate and the resultant properties of films deposited on the substrate. Accordingly, conventional vacuum chucks provide large chucking holes (for example, about 120 mils in diameter) to obtain the desired high vacuum chucking power. However, the inventors have discovered that significant “cool spots” can develop on the substrate in locations corresponding to the chucking holes. In addition, the inventors have discovered that locating the chucking holes in the intersections of the vacuum grooves (conventionally thought to more beneficially distribute the vacuum pressure within the various grooves) actually exacerbates the “cool spot” phenomenon.

In addition to the “cool spots” caused by conventional chucking hole sizes and locations, the inventors have further discovered that the non-axisymmetrical layout of some conventional groove patterns further causes a non-axisymmetrical temperature profile, and thus, a non-axisymmetrical film thickness profile, on the substrate.

Moreover, the inventors have further discovered that variations from heater to heater may further have large effects on resultant deposited film thicknesses. For example, when replacing heaters (due to a failure, maintenance, or the like) within a process chamber, the replacement heater will likely not provide the same thickness profile as the prior heater. Moreover, the heater-to-heater variation may be such that process standardization may be impossible or extremely difficult across multiple process chambers each with different vacuum heater chucks.

While some conventional systems utilizing vacuum chucking heaters may utilize control of flow rates of gases within the process chamber or within the vacuum chucking heater to attempt to compensate for the non-uniform thermal profile on the substrate, the thermal profile variation from heater to heater makes such compensation efforts difficult.

Accordingly, there is a need in the art for an improved vacuum chucking heater for processing substrates.

### SUMMARY OF THE INVENTION

Embodiments of a vacuum chuck having an axisymmetrical and/or more uniform thermal profile are provided herein. In some embodiments, a vacuum chuck includes a body having a support surface for supporting a substrate thereupon; a plurality of axisymmetrically arranged grooves formed in the support surface, at least some of the grooves intersecting; and a plurality of chucking holes formed through the body and within the grooves, the chucking holes for fluidly coupling the grooves to a vacuum source during operation, wherein the chucking holes are disposed in non-intersecting portions of the grooves.

In some embodiments, a substrate process chamber includes a process chamber; and a vacuum chuck disposed within the process chamber, the vacuum chuck includes a body having a support surface for supporting a substrate thereupon; a plurality of axisymmetrically arranged grooves formed in the support surface, at least some of the grooves intersecting; and a plurality of chucking holes formed through the body and within the grooves, the chucking holes for fluidly coupling the grooves to a vacuum source during operation, wherein the chucking holes are disposed in non-intersecting portions of the grooves.

In another aspect of the invention, methods of fabricating a vacuum chuck are provided. In some embodiments, a method of fabricating a vacuum chuck includes providing a body having a substrate support surface; forming a plurality of axisymmetrically arranged grooves in the support surface; and forming a plurality chucking holes through the body within non-intersecting portions of the grooves.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A depicts a top view of a vacuum chucking heater in accordance with some embodiments of the present invention.

FIG. 1B depicts a cross-sectional side view of the vacuum chucking heater of FIG. 1A taken along section line 1B-1B.

FIG. 2 depicts a flow chart of a method of fabricating a vacuum chucking heater in accordance with some embodiments of the invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide a vacuum chucking heater having an axisymmetrical and/or more uniform thermal profile. As used herein, the term “thermal profile” refers to the steady state temperature of a substrate or work piece disposed on a vacuum chucking heater and heated to a desired temperature. As used herein, the term “axisymmetrical” refers to a symmetry of the thermal profile with respect to a central axis of the vacuum chucking heater or a substrate disposed thereon, for example, an axis extending perpendicularly from a center of a semiconductor wafer or substrate.

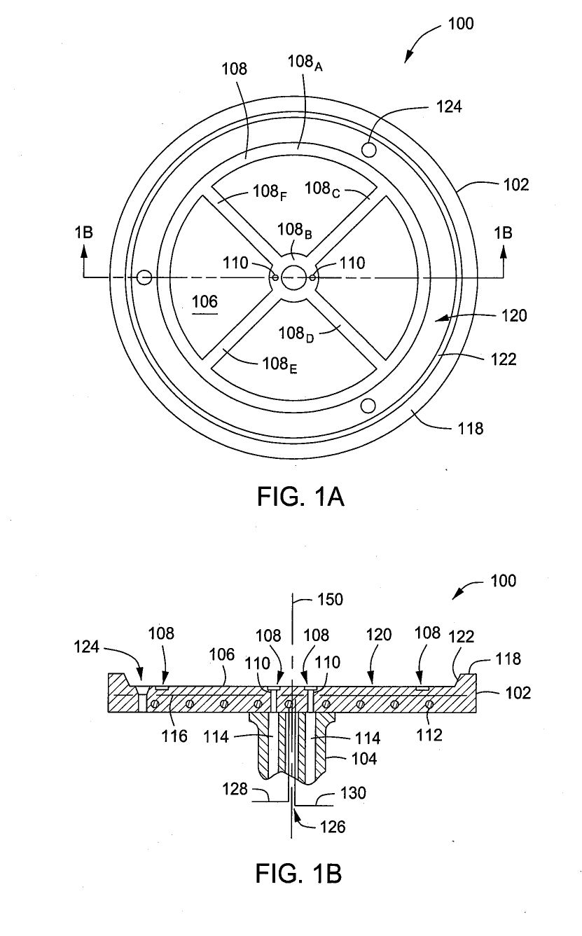

FIGS. 1A-B respectively depict a top view and a cross-sectional side view taken along section line 1B-1B of a vacuum chucking heater 100 in accordance with some embodiments of the present invention. The vacuum chucking heater 100 may be disposed in a process chamber (not shown) for use in processing substrates, for example semiconductor substrates (such as, but not limited to, 200 or 300 mm semiconductor wafers). The vacuum chucking heater 100 may be used in any process where heating of the substrate is desired, such as, chemical vapor deposition (CVD), physical vapor deposition (PVD), or the like. Suitable process chambers that may benefit from vacuum chucking heaters as described herein include the sub-atmospheric CVD (SACVD) line of process chambers utilized in, for example, the PRODUCERS semiconductor processing system, all available from Applied Materials, Inc., of Santa Clara, Calif. It is contemplated that the vacuum chucking heaters of the present invention may be utilized in other process chambers and systems as well.

The vacuum chucking heater 100 comprises a body 102 having a heater 112 disposed therein (such as a resistive heater element, or the like) and a shaft 104 for supporting the body 102. The body 102 may be made out of any materials suitable to withstand processing conditions, such as aluminum nitride, aluminum oxide, stainless steel, aluminum, pyrolytic boron nitride, or the like. The body 102 has a substantially planar support surface 106 for supporting a substrate thereupon. In some embodiments, a peripheral protrusion or lip 118 may be provided to define a pocket 120 where the substrate may be situated during processing. The lip 118 may have a feature 122 (such as an angled sidewall) that facilitates centering and retaining the substrate in a desired position during processing. A plurality of lift pins holes 124 may be provided (three lift pin holes 124 depicted in FIGS. 1A-B) with corresponding lift pins (not shown) to facilitate raising and lowering the substrate onto and off of the support surface 106.

The heater 112 generally comprises one or more resistive coils (not shown) embedded in the body 102. The resistive coils may be independently controllable to create heater zones. A temperature indicator (not shown) may be provided to monitor the processing temperature. As one example, the temperature indicator can be a thermocouple (not shown), positioned such that it provides data correlating to the temperature at the support surface 106 (or at the surface of a substrate disposed thereon).

In some embodiments, an RF electrode 116 may be provided within the body 102 to facilitate one or both of coupling RF power to the chamber or providing an RF ground path to remove RF power from the chamber.

To facilitate vacuum chucking, one or more grooves 108 are formed in the support surface 106 and a plurality of chucking holes 110 are provided within the grooves 108. The grooves 108 may be formed in any suitable manner, such as during a molding, casting, or sintering process to form the body 102, and/or by machining the support surface 106 of the body 102. The grooves 108 may further be formed in a conventional vacuum heater chuck (or a vacuum heater chuck 100 may be refurbished) by removing any existing grooves (such as by filling or machining the support surface) and then machining grooves 108 in accordance with the teachings provided herein.

In some embodiments of the present invention, the chucking holes 110 have a reduced diameter as compared to conventional vacuum heater chucks, thereby eliminating or reducing the “cool spot” effect. In some embodiments, the chucking holes 110 may have a diameter of less than or equal to about 40 mils, or between about 30-60 mils, or about 40 mils.

In some embodiments of the present invention, the chucking holes 100 may be disposed in locations remote from any intersections of respective grooves 108 (e.g., the chucking holes 100 are disposed in non-intersecting portions of the grooves). In some embodiments, the chucking holes 110 may be symmetrically (although not necessarily axisymmetrically) arranged. For example, in the embodiment depicted in FIGS. 1A-B, a pair of chucking holes 110 are provided in diametrically opposed locations within the groove 108 and equidistantly spaced from the nearest intersections of the grooves 108. It is contemplated that other greater or fewer chucking holes 110 may be utilized in different locations within the grooves (except, as noted above, not within any groove intersections).

In some embodiments of the invention, the grooves 108 are axisymmetrically arranged about a central axis 150 of the vacuum chucking heater 100, thereby advantageously facilitating the generation of an axisymmetrical thermal profile and, thereby, of an axisymmetrical film thickness profile. For example, in the embodiment depicted in FIGS. 1A-B, an inner circular groove 108_{A} and an outer circular groove 108_{B} are provided with four equidistantly spaced radial grooves 108_{C-F} connecting the inner and outer circular grooves 108_{A-B}. It is contemplated that other axisymmetrical geometric configurations may be utilized having the same or different numbers of grooves.

The axisymmetrically arranged grooves 108 result in uniform distribution of gas pressure between the substrate and the support surface 106 of the vacuum heater chuck 100. This, in turn, causes uniform heat transfer between the vacuum heater chuck 100 and the substrate, thereby resulting in a more uniform temperature profile of the substrate. For example, testing results show that the azimuthal temperature range of a substrate disposed on the vacuum heater chuck 100 can be reduced from 6 degrees Celsius to less than about 3 degrees Celsius, thereby reducing reliance on other means to attempt to compensate for thermal profile non-uniformities.

In some embodiments of the present invention, the grooves 108 may have tight tolerances, thereby advantageously reducing heater-to-heater temperature profile variation. For example, in some embodiments, the grooves 108 may have a width of between about 17-23 mils. In some embodiments, the grooves 108 may have a depth of between about 2.5-3.5 mils. Moreover, in some embodiments, the support surface 106 may have a reduced surface roughness of less than about 32 microinches, or between about 28-32 microinches, thereby improving the surface contact between the substrate and the support surface 106 during use. Thus, the heater to heater variation of substrate temperature may be controlled by tightly controlling the topographical conditions of the surface of the vacuum heater chuck 100.

The shaft 104 may have a plurality of openings 114 (or other mechanism, such as tubes, hoses, or the like) that fluidly couple the chucking holes 110 (and thereby the grooves 108) to a vacuum system (not shown). Accordingly, in operation, a substrate may be disposed on the support surface 106 of the vacuum heater chuck 100 and retained thereon by application and maintenance of vacuum pressure within the grooves 108 via the chucking holes 110. The shaft 104 further comprises a central passageway 126 to facilitate routing of facilities or connectors to the body 102 of the vacuum heater chuck 100. For example, one or more heater connectors 128 may be routed through the passageway 126 and coupled to the heater 112 for providing electrical connection to operate the heater 112. In addition, an RF connector 130 may be routed through the passageway 126 for coupling the RF electrode 116 to an RF power supply or ground connection (not shown).

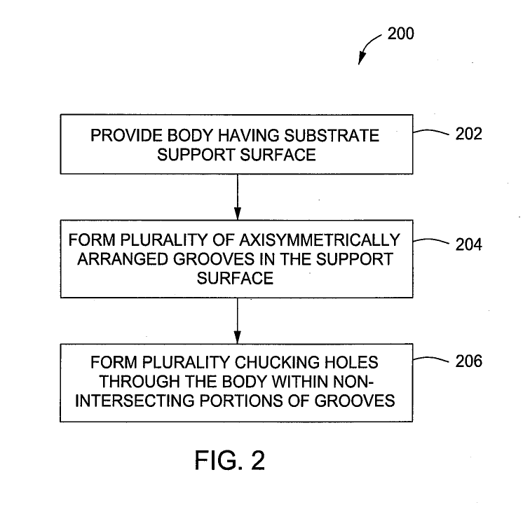

FIG. 2 depicts a flow chart of a method 200 of fabricating a vacuum chucking heater in accordance with some embodiments of the invention. The method 200 is described with reference to the vacuum chucking heater 100 described above with respect to FIGS. 1A-B. In some embodiments, the method begins at 202 wherein a body 102 having a substrate support surface 106 is provided. The body 102 may be fabricated from any suitable materials as discussed above and may be fabricated in any suitable manner, such as by molding, sintering, machining, or the like.

Next at 204, a plurality of axisymmetrically arranged grooves 108 may be formed in the support surface 106. The grooves 108 may be formed in any suitable manner, such as during the fabrication process for forming the body 102. Alternatively, the grooves 108 may be formed by subsequently machining the grooves into the support surface 106 of the body 102. In some embodiments, such as refurbishment of an existing vacuum chucking heater, pre-existing grooves may be removed from the body 102 prior to forming the grooves 108. For example, in some embodiments, the support surface 106 may be machined flat to remove the pre-existing grooves. It is contemplated that at least some of any pre-existing grooves may be re-conditioned rather than completely removed to form the grooves 108.

Next, at 206, a plurality of chucking holes 110 may be formed through the body within non-intersecting portions of the grooves 108. The chucking holes 110 may be formed either prior to or after the forming of the grooves 108. Moreover, in embodiments where the vacuum chucking heater is being refurbished, the chucking holes 110 may already exist within the body 102 or may be subsequently formed. In addition, in embodiments where the vacuum chucking heater is being refurbished, any pre-existing chucking holes may be at least partially filled prior to forming the chucking holes 110.

Thus, embodiments of a vacuum chucking heater of axisymmetrical and uniform thermal profile have been provided herein. The vacuum chucking heater advantageously minimizes thickness non-uniformity of films and/or coatings formed on substrates disposed on the vacuum chucking heater. Moreover, the inventive vacuum chucking heaters described herein further advantageously provide one or more of: 1) reduction of film thickness spikes due to local cold spots on a substrate corresponding to chucking holes, 2) reduction of film thickness profile asymmetry due to thermal profile asymmetry of the vacuum chucking heater, and 3) reduction in heater-to-heater thermal profile variation.

While the foregoing is directed to embodiments of the present invention, other and further embodiments of the invention may be devised without departing from the basic scope thereof, and the scope thereof is determined by the claims that follow.

1. A vacuum chuck, comprising:
a body having a support surface for supporting a substrate thereupon;
a plurality of axisymmetrically arranged grooves formed in the support surface, at least some of the grooves intersecting; and
a plurality of chucking holes formed through the body and within the grooves, the chucking holes for fluidly coupling the grooves to a vacuum source during operation, wherein the chucking holes are disposed in non-intersecting portions of the grooves.

2. The vacuum chuck of claim 1, further comprising:
a heater disposed within the body.

3. The vacuum chuck of claim 2, wherein the heater comprises:
one or more resistive coils.

4. The vacuum chuck of claim 1, wherein the grooves have a width of between 17-23 mils.

5. The vacuum chuck of claim 1, wherein the grooves have a depth of between 2.5-3.5 mils.

6. The vacuum chuck of claim 1, wherein the support surface has a surface roughness of less than or equal to 32 microinches.

7. The vacuum chuck of claim 1, wherein the holes have a diameter of between 20-60 mils.

8. The vacuum chuck of claim 1, wherein the holes have a diameter of less than or equal to 40 mils.

9. The vacuum chuck of claim 1, wherein the holes have a diameter of less than a width of the grooves.

10. The vacuum chuck of claim 1, wherein the plurality of chucking holes are two chucking holes.

11. The vacuum chuck of claim 1, wherein the plurality of chucking holes are symmetrically arranged about a central axis of the vacuum chuck.

12. The vacuum chuck of claim 1, wherein the plurality of axisymmetrically arranged grooves comprises at least two concentric circular grooves having a plurality of radially extending grooves coupling the circular grooves.

13. A substrate process chamber, comprising:
a process chamber; and
a vacuum chuck disposed within the process chamber, the vacuum chuck comprising:
a body having a support surface for supporting a substrate thereupon;
a plurality of axisymmetrically arranged grooves formed in the support surface, at least some of the grooves intersecting; and
a plurality of chucking holes formed through the body and within the grooves, the chucking holes for fluidly coupling the grooves to a vacuum source during operation, wherein the chucking holes are disposed in non-intersecting portions of the grooves.

14. The vacuum chuck of claim 13, further comprising:
a vacuum pump coupled to the chucking holes for establishing and maintaining vacuum pressure within the grooves during processing.

15. The vacuum chuck of claim 13, further comprising:
a heater disposed within the body.

16. The vacuum chuck of claim 13, wherein the grooves have a width of between 17-23 mils and a depth of between 2.5-3.5 mils.

17. The vacuum chuck of claim 13, wherein the support surface has a surface roughness of less than or equal to 32 microinches.

18. The vacuum chuck of claim 13, wherein the holes have a diameter of between 20-60 mils.

19. The vacuum chuck of claim 13, wherein the plurality of chucking holes are two chucking holes symmetrically arranged about a central axis of the vacuum chuck.

20. The vacuum chuck of claim 13, wherein the plurality of axisymmetrically arranged grooves comprises at least two concentric circular grooves having a plurality of radially extending grooves coupling the circular grooves.

21. A method of fabricating a vacuum chuck, comprising:
providing a body having a substrate support surface;
forming a plurality of axisymmetrically arranged grooves in the support surface; and
forming a plurality chucking holes through the body within non-intersecting portions of the grooves.

22. The method of claim 21, wherein providing a body further comprises:
removing pre-existing grooves from the body.

23. The method of claim 22, further comprising:
machining the support surface to remove the pre-existing grooves.
